(19) United States
(12) Patent Application Publication
(10) Pub. No.: US 2006/0134816 A1
(43) Pub. Date: Jun. 22, 2006

(54) Semiconductor laser device of III-V group compound and fabrication method therefor

(75) Inventor: Hiroyuki Hosoba, Soraku-gun (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/338,129

(22) Filed: Jan. 23, 2006

Related U.S. Application Data
(62) Division of application No. 10/639,208, filed on Aug. 11, 2003.

(30) Foreign Application Priority Data
Aug. 20, 2002 (JP) JP2002-239020

(51) Int. Cl. H01L 21/00

(52) U.S. Cl. 438/46

(57) ABSTRACT

A semiconductor laser device of a III-V group compound includes a substrate including a main surface having an inclination angle of less than 20° toward a [011] direction from a (100) plane and an inclined facet further inclined toward the [011] direction from the main surface, a light emitting stacked-layered portion including at least an active layer and a clad layer over the substrate, and a current-constricting layer including a IV group impurity. The current-constricting layer has a region of an n type conductivity above the main surface of the substrate, and a region of a p type conductivity above the inclined facet of the substrate.

### BACKGROUND OF THE INVENTION

1. Field of the Invention

The present invention relates to a semiconductor laser device of a III-V group compound and a fabrication method therefor, and particularly to improvement of a current-constricting layer included in the laser device and improvement of a formation method therefor.

2. Description of the Background Art

A semiconductor laser device using an AlGaInP-based semiconductor material has been applied to development of a light emitting device of a visible light range, since such a laser device can have lattice matching with a GaAs substrate and it also has the greatest direct transition bandgap among the semiconductors of III-V group compounds. In particular, the AlGaInP-based semiconductor material has been used to form a light emitting device of a visible light range for a light source enabling higher density recording on an audio/video optical disk.

Recently, there has been a demand for low costs as well as high reliability at a high output operation regarding the laser device, and laser structures meeting such a demand have been proposed. For example, a conventional semiconductor laser device shown in a schematic cross section in FIG. 10 is disclosed Japanese Patent Laying-Open No. 7-263796, which can be formed through sequential epitaxial crystal growth.

The laser device of FIG. 10 includes an n type GaAs substrate 801, an n type GaAs buffer layer 802, an n type GaInP intermediate layer 803, an n type AlGaInP clad layer 804, an n type AlGaInP guide layer 805, a GaInP/AlGaInP multiple quantum well (MQW) active layer 806, a p type AlGaInP guide layer 807, a p type AlGaInP clad layer 808, an AlGaInP current-constricting layer 809, a p type region 809b, an n type region 809a, a p type AlGaInP clad layer 810, a p type GaInP intermediate layer 811, and a p type GaAs contact layer 812. An electrode for n type 10 is formed on the back side of n type GaAs substrate 801, and an electrode for p type 11 is formed on p type GaAs contact layer 812.

Substrate 801 has a main surface of a (100) plane, and an inclined facet of a (311) B plane. A semiconductor multilayered structure is formed on this substrate by MOCVD (metallorganic chemical vapor deposition). By simultaneously doping Zn and Se during deposition of current-constricting layer 809, it is possible that the region 809a of the current-constricting layer above the main surface of the substrate becomes an n type region, while the region 809b of the current-constricting layer above the inclined facet of the substrate becomes a p type region, presumably for the following reasons.

Zn and Se have their segregation coefficients which change depending on the plane orientation of the underlayer. Specifically, the segregation coefficient of Zn increases, while that of Se decreases, as the underlayer surface approaches a (311) B plane. Thus, region 809a of the current-constricting layer above the main surface of the substrate becomes an n type region, and region 809b of the current-constricting layer above the inclined facet becomes a p type region. As such, a current-constricting type semiconductor laser can be fabricated through sequential crystal growth by MOCVD.

However, the conventional laser device shown in FIG. 10 requires use of Zn and Se as the impurities in current-constricting layer 809, causing a problem of diffusion of the impurities. Specifically, when the impurities of Zn and Se are diffused into p type AlGaInP clad layer 808 or GaInP/AlGaInP active layer 806, the impurities form non-radiative defect centers. In such a case, the introduced carriers fail to contribute to light emission efficiently, thereby causing degradation of laser characteristics and reliability.

In addition, since the laser device of FIG. 10 employs MOCVD, the substrate temperature is generally higher than in the case of using another crystal growth method, thereby further promoting diffusion of Zn and Se.

### SUMMARY OF THE INVENTION

In view of the foregoing, an object of the present invention is to provide, in a simple manner and at low costs, a semiconductor laser device of a III-V group compound in which degradation of its characteristics does not caused by impurities doped into a current-constricting layer and diffused into an active layer or the like.

According to the present invention, a semiconductor laser device of a III-V group compound includes a substrate including a main surface having an inclination angle within 20° toward a [011] direction from a (100) plane and an inclined facet further inclined toward the [011] direction from the main surface, a light emitting stacked-layered portion including at least an active layer and a clad layer over the substrate, and a current-constricting layer containing a IV group impurity. The current-constricting layer has a region of an n type conductivity above the main surface of the substrate, and a region of a p type conductivity above the inclined facet of the substrate.

The inclined facet of the substrate preferably has an inclination angle in a rage of 20° to 70° toward the [011] direction from the (100) plane. Further, the IV group impurity included in the current-constricting layer is preferably Si. The current-constricting layer may be provided above the active layer, or provided between the active layer and the substrate.

The current-constricting layer may be formed of either (AlₓGa₁₋ₓ)_{y}In_{1-y}P (0≦x≦1, 0≦y≦1) or AlₓGa₁₋ₓAs (0≦x1). The light emitting stacked-layered portion may also be formed of either (AlₓGa₁₋ₓ)_{y}In_{1-y}P (0≦x≦1, 0≦y≦1) or AlₓGa₁₋ₓAs (0≦x≦1). The light emitting stacked-layered portion preferably includes a quantum well active layer.

At least two such inclined facets of the substrate may be included in one semiconductor laser device chip. A plurality of light emitting portions for emitting light of laser wavelengths different from each other may be included in one semiconductor laser device chip.

According to the present invention, a method of fabricating a semiconductor laser device of a III-V group compound is characterized in that a light emitting stacked-layered portion including at least an active layer and a clad layer, and a current-constricting layer including a IV group impurity, are grown by molecular beam epitaxy on a substrate including a main surface having an inclination angle of less than 20° toward a [011] direction from a (100) plane and an inclined facet further inclined toward the [011] direction from the main surface, so that the current-constricting layer has a region of an n type conductivity above the main surface of the substrate and a region of a p type conductivity above the inclined facet of the substrate.

The growth temperature of the current-constricting layer during molecular beam epitaxy is preferably set to more than 400° C. Further, the pressure of a V group element during growth of the current-constricting layer by molecular beam epitaxy is preferably set to less than 1E-5hPa.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view of a semiconductor substrate for fabricating a semiconductor laser device according to a first embodiment of the present invention.

FIG. 2 is a schematic cross sectional view showing a multilayered semiconductor structure deposited on the substrate of FIG. 1.

FIG. 3 is a schematic cross sectional view of a semiconductor laser device of the first embodiment of the present invention.

FIG. 4 is a graph showing relation between the inclination angle of the substrate surface inclined toward the [011] direction from the (100) plane and the carrier concentration within the Si-doped AlGaInP current-constricting layer deposited above the substrate surface.

FIG. 5 is a graph showing relation between the MBE growth temperature of the Si-doped AlGaInP current-constricting layer and the carrier concentration within the current-constricting layer.

FIG. 6 is a graph showing relation between the pressure of the V group element during the MBE growth of the Si-doped AlGaInP current-constricting layer and the carrier concentration within the current-constricting layer.

FIGS. 7-9 are schematic cross sectional views of semiconductor laser devices according to second through fourth embodiments of the present invention, respectively.

FIG. 10 is a schematic cross sectional view of a conventional semiconductor laser device.

### DESCRIPTION OF THE PREFERRED EMBODIMENTS

### First Embodiment

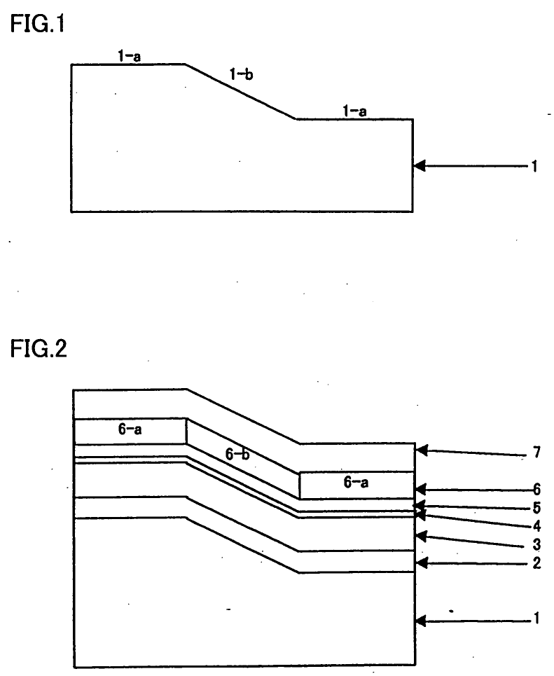

In FIGS. 1-3, a fabrication process of an AlGaInP-based semiconductor laser device according to a first embodiment of the present invention is shown in schematic cross sectional views. In the drawings of the present application, the same or corresponding portions are denoted by the same reference characters.

Referring to FIG. 1, an n type GaAs substrate 1 is firstly etched to form a main surface 1-a of a (100) plane and an inclined facet 1-b having a plane orientation inclined 40° toward a [011] direction from the (100) plane.

Next, referring to FIG. 2, an n type GaAs buffer layer 2, an n type AlGaInP clad layer 3, a GaInP active layer 4, a p type AlGaInP clad layer 5, a Si-doped AlGaInP current-constricting layer 6, and a p type GaAs cap layer 7 are successively stacked over n type GaAs substrate 1 of FIG. 1 by molecular beam epitaxy (MBE). Active layer 4 may include a single or multiple quantum wells.

Here, in Si-doped AlGaInP current-constricting layer 6, a region 6-a above main surface 1-a of the substrate shows an n type conductivity, and a region 6-b above inclined facet 1-b of the substrate shows a p type conductivity, presumably for the following reasons.

A substrate surface having a plane orientation largely inclined from the (100) plane toward the [011] direction is generally called an A plane in which there exist a large number of III group element atoms (Ga in this case) each having one dangling bond. Thus, the V group element atoms (P in this case) adsorbed to the III group element atoms (Ga in this case) at the surface shows a small adhesion coefficient, and are unlikely to remain in place stably. Si atoms as the impurity of the IV group element are likely to occupy lattice sites of the V group element atoms (P in this case), so that the surface tends to have the p type conductivity. By comparison, at a substrate surface close to the (100) plane, there exist a large number of V group element atoms (P in this case) each having two dangling bonds. Thus, Si atoms as the IV group element impurity are likely to occupy lattice sites of the III group element atoms (Ga in this case), so that the surface tends to have an n type conductivity.

Thus, in Si-doped AlGaInP current-constricting layer 6, region 6a above main surface 1-a of the substrate tends to have an n type conductivity and region 6b above inclined facet 1-b of the substrate tends to have a p type conductivity. Such a tendency becomes more remarkable as the inclined angle toward the [011] direction from the (100) plane increases.

The graph of FIG. 4 shows the relation between the inclination angle of the substrate surface inclined toward the [011] direction from the (100) plane and the carrier concentration within Si-doped AlGaInP current-constricting layer 6 formed on the substrate surface. In this graph, it is found that Si-doped current-constricting layer 6 grown above a substrate surface having an inclination angle of less than 20° shows an n type conductivity, and Si-Doped current-constricting layer 6 grown above a substrate surface having the inclination angle of more than 20° shows a p type conductivity. This is because, as the inclination angle of the substrate surface increases, an increased number of the III group element atoms (Ga in this case) each having one dangling bond exist at the surface.

In order to make Si-doped current-constricting layer 6 have a p type conductivity above a substrate surface inclined toward the [011] direction from the (100) plane, it is necessary to cause Si atoms as IV group element impurity to occupy the lattice sites of the V group element atoms. To this end, the crystal growth temperature (substrate temperature) at the time of MBE is raised, or a pressure of the V group element is decreased, to further enhance the effect of taking impurity Si atoms into the lattice sites of the V group element atoms.

FIG. 5 shows the relation between the MBE growth temperature and the carrier concentration within Si-doped AlGaInP current-constricting layer 6 in the case of using a substrate surface inclined 40° toward the [011] direction from the (100) plane. It is found from this graph that Si-doped current-constricting layer 6 has an n type conductivity with the growth temperature of less than 400° C. and it has a p type conductivity with the growth temperature of more than 400° C. This is presumably because migration of the V group element atoms (P in this case) adsorbed to the crystal growth surface increases as the MBE growth temperature is raised, so that the adhesion coefficient decreases. Thus, the MBE growth temperature is preferably more than 400° C. to make Si-doped current-constricting layer 6 of a p type.

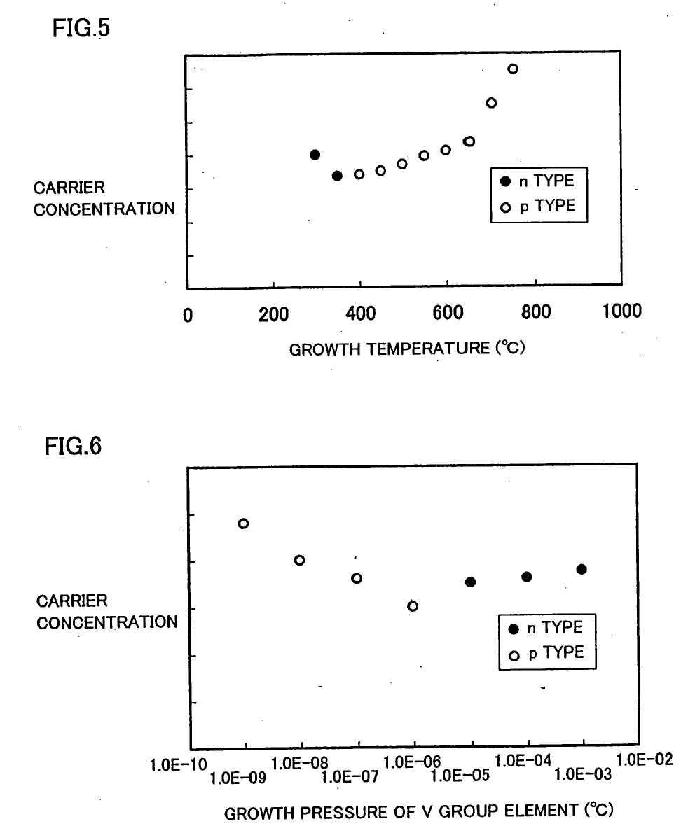

FIG. 6 shows the relation between the pressure of the V group element at the time of MBE growth and the carrier concentration within the Si-doped AlGaInP current-constricting layer, in the case of using a substrate surface inclined 40° toward the [011] direction from the (100) plane. Referring to FIG. 6, Si-doped current-constricting layer 6 has an n type conductivity when the pressure of the V group element (P in this case) at the time of MBE growth is not less than 1E-5hPa (1E-5 represents 1×10⁻⁵, and so on), whereas Si-doped current-constricting layer 6 has a p type conductivity with the pressure of the V group element of less than 1E-5hPa. This is presumably because it becomes easier for Si atoms as the IV group element impurity to occupy the lattice sites of the V group element atoms as the pressure of the V group element during the MBE growth decreases. As such, to make Si-doped current-constricting layer 6 have a p type conductivity, the pressure of the V group element (P in this case) during the MBE growth is preferably less than 1E-5hPa.

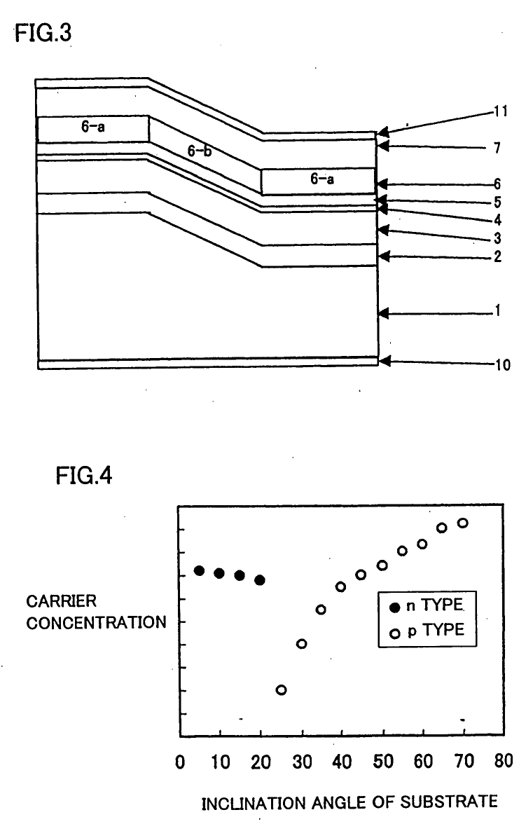

After n type GaAs buffer layer 2 to p type GaAs cap layer 7 are successively stacked over n type GaAs substrate 1 of FIG. 1 by MBE as shown in FIG. 2, electrode for n type 10 is formed on the back side of substrate 1, and electrode for p type 11 is formed on p type GaAs cap layer 7 as shown in FIG. 3. The semiconductor laser device of the III-V group compound of the first embodiment is thus completed.

In the semiconductor laser device of the III-V group compound shown in FIG. 3, current-constricting layer 6 sandwiched between p type clad layer 5 and p type cap layer 7 includes p type region 6-b through which electric current introduced from both electrodes 10, 11 are passed, and n type region 6-a where the current is blocked. That is, current-constricting layer 6 constricts the current so as to pass the current only through p type region 6-b, and thus the current is introduced into active layer 4 only beneath p type region 6-b. Of active layer 4, only this narrow region where the constricted current is introduced can emit light.

### Second Embodiment

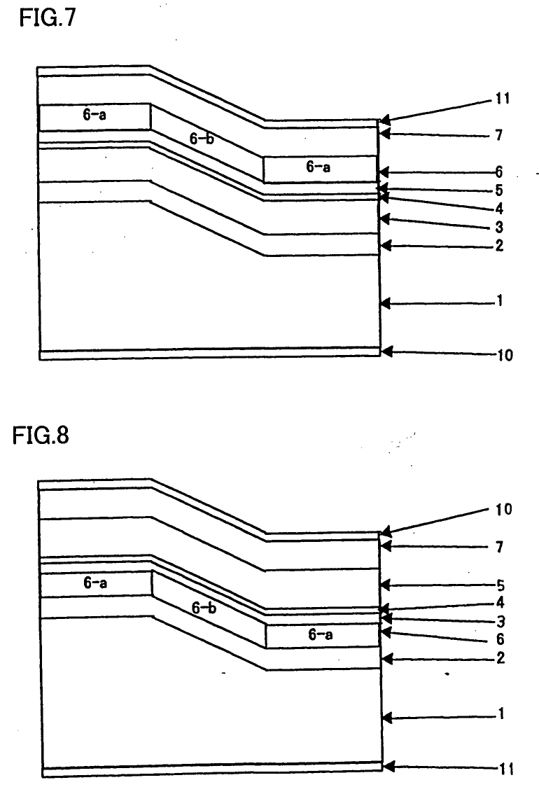

In FIG. 7, an AlGaAs-based semiconductor laser device according to a second embodiment of the present invention is shown in a schematic cross sectional view. The second embodiment differs from the first embodiment in that the light emitting portion including the active layer and the clad layer, and the current-constricting layer are formed of AlₓGa₁₋ₓAs (0≦x≦1).

Specifically, the semiconductor laser device of the III-V group compound shown in FIG. 7 includes an n type GaAs buffer layer 2, an n type AlGaAs clad layer 3, an AlGaAs active layer 4, a p type AlGaAs clad layer 5, a Si-doped AlGaAs current-constricting layer 6, and a p type GaAs cap layer 7 successively grown over an n type GaAs substrate 1 by MBE. An electrode for n type 10 is formed on the back side of n type GaAs substrate 1, and an electrode for p type 11 is formed on p type GaAs cap layer 7.

In the second embodiment, similarly to the case of the first embodiment, a region 6-a of Si-doped AlGaAs current-constricting layer 6 shows an n type conductivity, and a region 6-b shows a p type conductivity. Such an AlGaAs-based semiconductor laser device can be fabricated so as to emit light of laser wavelength in the vicinity of 780 nm.

### Third Embodiment

In FIG. 8, a semiconductor laser device of a III-V group compound according to a third embodiment of the present invention is shown in a schematic cross sectional view. The third embodiment differs from the first embodiment in that a p type GaAs substrate is employed and correspondingly a current-constricting layer is formed between the substrate and an active layer.

Specifically, the semiconductor laser device of the III-V group compound shown in FIG. 8 includes a p type GaAs buffer layer 2, a Si-doped AlGaInP current-constricting layer 6, a p type AlGaInP clad layer 3, a GaInP active layer 4, an n type AlGaInP clad layer 5, and an n type GaAs cap layer 7 successively grown over a p type GaAs substrate 1 by MBE. An electrode for p type 11 is formed on the back side of p type GaAs substrate 1, and an electrode for n type 10 is formed on n type GaAs cap layer 7.

In the semiconductor laser device of the III-V group compound of the third embodiment including a multilayered semiconductor structure having the opposite conductivities from those in the first embodiment, the effect of the present invention can similarly be obtained by changing the inserting position of Si-doped current-constricting layer 6 as appropriate.

### Fourth Embodiment

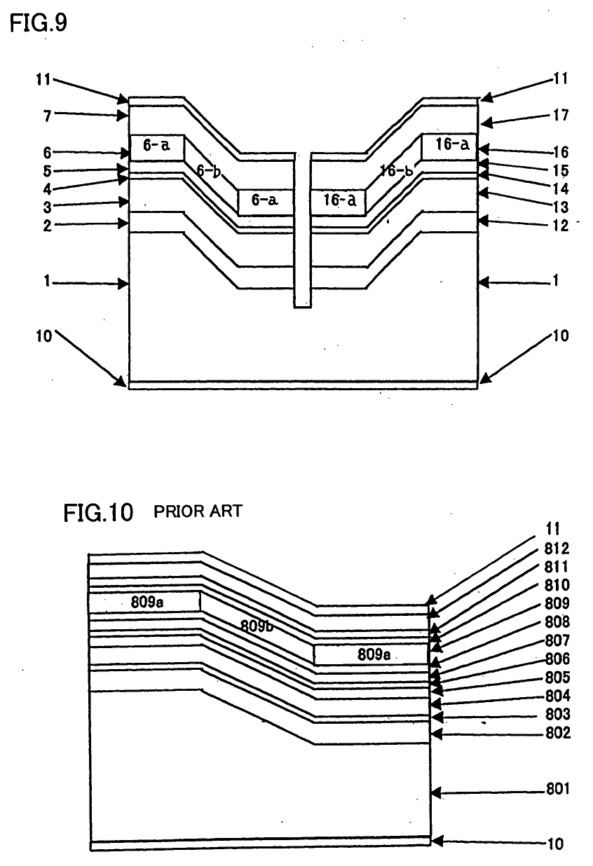

In FIG. 9, a semiconductor laser device of a III-V group compound according to a fourth embodiment of the present invention is shown in a schematic cross sectional view. The fourth embodiment is characterized in that two light emitting portions are formed in a laser device chip, and they are different in laser wavelength from each other.

Specifically, the semiconductor laser device chip of the III-V group compound shown in FIG. 9 includes, over the left half of an n type GaAs substrate 1, an n type GaAs buffer layer 2, an n type AlGaInP clad layer 3, a GaInP active layer 4, a p type AlGaInP clad layer 5, a Si-doped AlGaInP current-constricting layer 6, and a p type GaAs cap layer 7 successively grown by MBE. It further includes, over the right half of n type GaAs substrate 1, an n type GaAs substrate 11, an n type GaAs buffer layer 12, an n type AlGaAs clad layer 13, an AlGaAs active layer 14, a p type AlGaAs clad layer 15, a Si-doped AlGaAs current-constricting layer 16, and a p type GaAs cap layer 17 successively grown by MBE.

The semiconductor stacked-layered structure of FIG. 9 can be formed, e.g., as follows. Firstly, n type GaAs buffer layer 2 to p type GaAs cap layer 7 are grown by MBE over the entire surface of substrate 1. In the right half region of substrate 1, n type GaAs buffer layer 2 to p type GaAs cap layer 7 are etched away. Thereafter, in a state that n type GaAs buffer layer 2 to p type GaAs cap layer 7 on the left half region of substrate 1 are being protected, e.g., by a mask, n type GaAs buffer layer 12 to p type GaAs cap layer 17 are grown by MEB on the right half region of substrate 1. It is needless to say that the unnecessary regions of n type GaAs buffer layer 12 to p type GaAs cap layer 17 grown by MBE can be etched away.

An electrode for n type 10 is formed on the back side of n type GaAs substrate 1, and electrodes for p type 11 are formed on p type GaAs cap layers 7, 17.

Compared to the substrate surface inclined to the [011] direction from the (100) plane, the substrate surface inclined to the opposite (negative) direction has the similar properties. Thus, in Si-doped AlGaAs current-constricting layers 6 and 16, both regions 6-a and 16-a can have an n type conductivity, and both regions 6-b and 16-b can have a p type conductivity.

The semiconductor laser device chip of the III-V group compound shown in FIG. 9 includes two kinds of active layers of GaInP active layer 4 and AlGaAs active layer 14. Thus, it can emit light of two laser wavelengths. Needless to say, active layers 4, 14 each may include a single or multiple quantum wells.

As described above, according to the present invention, a substrate including a surface inclined-a prescribed angle toward a [011] direction from a (001) plane is utilized. Thus, it is possible to provide, in a simple manner and at low costs, a semiconductor laser device of a III-V group compound in which degradation in its characteristics is not caused by the impurity having been introduced in the current-constricting layer and diffused into the active layer or the like.

Although the present invention has been described and illustrated in detail, it is clearly understood that the same is by way of illustration and example only and is not to be taken by way of limitation, the spirit and scope of the present invention being limited only by the terms of the appended claims.

1-10. (canceled)

11. A method of fabricating a semiconductor laser device of a III-V group compound, wherein a light emitting stacked-layered portion including at least an active layer and a clad layer, and a current-constricting layer including a IV group impurity, are grown by molecular beam epitaxy over a substrate including a main surface having an inclination angle of less than 20° toward a [011] direction from a (100) plane and an inclined facet further inclined toward the [011] direction from the main surface,
said current-constricting layer including a region of an n type conductivity above said main surface and a region of a p type conductivity above said inclined facet.

12. The method of fabricating a semiconductor laser device of a III-V group compound according to claim 11, wherein a growth temperature of said current-constricting layer in said molecular beam epitaxy is set to more than 400° C.

13. The method of fabricating a semiconductor laser device of a III-V group compound according to claim 11, wherein a pressure of a V group element during growth of said current-constricting layer in said molecular beam epitaxy is set to less than 1E-5hPa.
